(19) United States
(12) Patent Application Publication
(10) Pub. No.: US 2022/0205082 A1
(43) Pub. Date: Jun. 30, 2022

(54) ZINC-COATED STEEL HAVING REDUCED SUSCEPTIBILITY FOR LIQUID METAL EMBRITTLEMENT (LME)

(71) Applicant: GM GLOBAL TECHNOLOGY OPERATIONS LLC, Detroit, MI (US)

(72) Inventors: Qi LU, Shanghai (CN); Jianfeng WANG, Nanjing (CN)

(73) Assignee: GM GLOBAL TECHNOLOGY OPERATIONS LLC, Detroit, MI (US)

(21) Appl. No.: 17/564,616

(22) Filed: Dec. 29, 2021

(30) Foreign Application Priority Data
Dec. 31, 2020 (CN) 202011617063.3

(51) Int. Cl. C23C 16/06; C23C 16/44; C23C 16/02; C22C 38/18; C22C 38/02

(52) U.S. Cl. CPC C23C 16/06; C23C 16/44; C22C 38/02; C22C 38/18; C23C 16/02

(57) ABSTRACT

A method of manufacturing zinc-coated steel having a reduced susceptibility to liquid metal embrittlement (LME) according to various aspects of the present disclosure includes providing a steel substrate including iron, carbon in amount ranging from about 0.01-0.45 weight percent, chromium in an amount ranging from about 0.5-5 weight percent, and silicon in an amount ranging from about 0.5-2.5 weight percent. The method includes forming an oxide-containing layer on a surface of the steel substrate by annealing the steel substrate in an oxygen-containing atmosphere. The method further coating a zinc layer on the oxide-containing layer by a spray coating process. In certain aspects, the present disclosure also provides a method of forming an assembly having a reduced susceptibility to LME via resistance spot welding. The present disclosure also provides, in various aspects, a zinc-coated steel component including a steel substrate, an oxide-containing layer, and a zinc layer.

### CROSS-REFERENCE TO RELATED APPLICATIONS

This application claims the benefit and priority of Chinese Application No. 202011617063.3, filed Dec. 31, 2020. The entire disclosure of the above application is incorporated herein by reference.

### INTRODUCTION

This section provides background information related to the present disclosure which is not necessarily prior art.

The present disclosure relates to zinc-coated steel having a reduced susceptibility for liquid metal embrittlement (LME), methods of manufacturing zinc-coated steel having a reduced susceptibility for LME, and methods of manufacturing high-strength, corrosion-resistant assemblies.

Advanced high-strength steels (AHSS) are useful in forming components or assemblies for automobiles due to their high strength and high ductility. AHSS may be zinc coated to reduce corrosion. However, manufacturing processes for zinc-coated AHSS are limited because the AHSSs may experience liquid metal embrittlement (LME) when exposed to liquid zinc.

### SUMMARY

This section provides a general summary of the disclosure, and is not a comprehensive disclosure of its full scope or all of its features.

In various aspects, the present disclosure provides a method of manufacturing zinc-coated steel having a reduced susceptibility to liquid metal embrittlement (LME). The method includes providing a steel substrate. The steel substrate includes iron, carbon in amount ranging from about 0.01-0.45 weight percent, chromium in an amount ranging from about 0.5-5 weight percent, and silicon in an amount ranging from about 0.5-2.5 weight percent. The method further includes forming an oxide-containing layer on a surface of the steel substrate by annealing the steel substrate in an oxygen-containing atmosphere. The method further includes coating a zinc layer on the oxide-containing layer by a spray coating process.

In one aspect, the forming the oxide-containing layer includes annealing the steel substrate at a dew point control of less than about 10° C.

In one aspect, the oxygen-containing atmosphere includes the oxygen at less than 10 volume percent and the oxygen-containing atmosphere further includes nitrogen, hydrogen, or both nitrogen and hydrogen.

In one aspect, the forming the oxide-containing layer includes annealing the steel substrate at a temperature in a range of about 500-950° C.

In one aspect, the forming the oxide-containing layer includes annealing the steel substrate for a duration of about 1-10,000 seconds.

In one aspect, the duration is about 60-600 seconds.

In one aspect, the spray coating process includes electric galvanizing, chemical vapor deposition, physical vapor deposition, jet vapor deposition, or any combination thereof.

In one aspect, the spray coating process includes jet vapor deposition.

In one aspect, the forming the oxide-containing layer includes forming a first oxide-containing layer on a first surface of the steel substrate and forming a second oxide-containing layer on a second surface of the steel substrate opposite the first surface. The coating the zinc layer includes coating a first zinc layer on the first oxide-containing layer and coating a second zinc layer on the second oxide-containing layer.

In one aspect, the oxide-containing layer defines a thickness in a range of about 0.01-5 μm.

In one aspect, the oxide-containing layer has a porosity of less than or equal to about 10%.

In various aspects, the present disclosure provides a method of creating a zinc-coated-steel assembly having reduced LME. The method includes providing a first zinc-coated steel component including a first steel substrate, a first oxide-containing layer on a surface of the steel substrate, and a first zinc layer on a surface of the oxide-containing layer. The first steel substrate includes iron, carbon in amount ranging from about 0.01-0.45 weight percent, chromium in an amount ranging from about 0.5-5 weight percent, and silicon in an amount ranging from about 0.5-2.5 weight percent. The method further includes providing a second zinc-coated steel component including a second steel substrate, a second oxide-containing layer on a surface of the steel substrate, and a second zinc layer on a surface of the oxide-containing layer. The second steel substrate includes iron, carbon in amount ranging from about 0.01-0.45 weight percent, chromium in an amount ranging from about 0.5-5 weight percent, and silicon in an amount ranging from about 0.5-2.5 weight percent. The method further includes arranging the first zinc-coated steel component and the second zinc-coated steel component so that the first zinc layer is in contact with the second zinc layer. The method further includes forming the assembly by resistance spot welding the first zinc-coated steel component to the second zinc-coated steel component.

In one aspect, the method further includes, prior to the forming, stamping the first zinc-coated steel component and stamping the second zinc-coated steel component.

In various aspects, the present disclosure provides a zinc-coated steel component. The zinc-coated steel component includes a steel substrate, an oxide-containing layer, and a zinc layer. The steel substrate includes iron, carbon in amount ranging from about 0.01-0.45 weight percent, chromium in an amount ranging from about 0.5-5 weight percent, and silicon in an amount ranging from about 0.5-2.5 weight percent. The oxide-containing layer is on a surface of the steel substrate. The zinc layer is on the oxide-containing layer.

In one aspect, the oxide-containing layer has a porosity of less than or equal to about 10%.

In one aspect, the oxide-containing layer defines a thickness in a range of about 0.01-5 μm.

In one aspect, the thickness is in a range of about 0.1-1 μm.

In one aspect, the oxide-containing layer includes iron, oxygen, chromium, and silicon.

In one aspect, the chromium is present in an amount ranging from about 0.1-50 weight percent. The silicon is present in an amount ranging from about 0.1-30 weight percent. In one aspect, the oxide-containing layer includes a first oxide-containing layer on a first surface of the steel substrate and a second oxide-containing layer on a second surface of the steel substrate opposite the first surface/The zinc layer includes a first zinc layer on the first oxide-containing layer and a second zinc layer on the second oxide-containing layer.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

The drawings described herein are for illustrative purposes only of selected embodiments and not all possible implementations, and are not intended to limit the scope of the present disclosure.

FIG. 1 is a flowchart depicting a method of manufacturing a high-strength, corrosion-resistant steel assembly according to various aspects of the present disclosure;

FIG. 2 is a sectional view of a steel substrate according to various aspects of the present disclosure;

FIG. 3 is a sectional view of a pre-oxidized steel substrate including the steel substrate of FIG. 2 according to various aspects of the present disclosure;

FIG. 4 is a sectional view of a zinc-coated steel substrate including the pre-oxidized steel substrate of FIG. 3 according to various aspects of the present disclosure;

FIG. 5 is a schematic view of a resistance spot welding process including components formed from the zinc-coated steel substrate of FIG. 4 according to various aspects of the present disclosure;

FIG. 6 is a scanning electron microscope (SEM) image of a pre-oxidized steel substrate according to various aspects of the present disclosure; and

FIG. 7 is an SEM image of a pre-oxidized steel substrate according to various aspects of the present disclosure.

Corresponding reference numerals indicate corresponding parts throughout the several views of the drawings.

### DETAILED DESCRIPTION

Example embodiments are provided so that this disclosure will be thorough, and will fully convey the scope to those who are skilled in the art. Numerous specific details are set forth such as examples of specific compositions, components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, elements, compositions, steps, integers, operations, and/or components, but do not preclude the presence or addition of one or more other features, integers, steps, operations, elements, components, and/or groups thereof. Although the open-ended term “comprising,” is to be understood as a non-restrictive term used to describe and claim various embodiments set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, the present disclosure also specifically includes embodiments consisting of, or consisting essentially of, such recited compositions, materials, components, elements, features, integers, operations, and/or process steps. In the case of “consisting of,” the alternative embodiment excludes any additional compositions, materials, components, elements, features, integers, operations, and/or process steps, while in the case of “consisting essentially of,” any additional compositions, materials, components, elements, features, integers, operations, and/or process steps that materially affect the basic and novel characteristics are excluded from such an embodiment, but any compositions, materials, components, elements, features, integers, operations, and/or process steps that do not materially affect the basic and novel characteristics can be included in the embodiment.

Any method steps, processes, and operations described herein are not to be construed as necessarily requiring their performance in the particular order discussed or illustrated, unless specifically identified as an order of performance. It is also to be understood that additional or alternative steps may be employed, unless otherwise indicated.

When a component, element, or layer is referred to as being “on,” “engaged to,” “connected to,” or “coupled to” another element or layer, it may be directly on, engaged, connected or coupled to the other component, element, or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various steps, elements, components, regions, layers and/or sections, these steps, elements, components, regions, layers and/or sections should not be limited by these terms, unless otherwise indicated. These terms may be only used to distinguish one step, element, component, region, layer or section from another step, element, component, region, layer or section. Terms such as “first,” “second,” and other numerical terms when used herein do not imply a sequence or order unless clearly indicated by the context. Thus, a first step, element, component, region, layer or section discussed below could be termed a second step, element, component, region, layer or section without departing from the teachings of the example embodiments.

Spatially or temporally relative terms, such as “before,” “after,” “inner,” “outer,” “beneath,” “below,” “lower,” “above,” “upper,” and the like, may be used herein for ease of description to describe one element or feature's relationship to another element(s) or feature(s) as illustrated in the figures. Spatially or temporally relative terms may be intended to encompass different orientations of the device or system in use or operation in addition to the orientation depicted in the figures.

Throughout this disclosure, the numerical values represent approximate measures or limits to ranges to encompass minor deviations from the given values and embodiments having about the value mentioned as well as those having exactly the value mentioned. Other than in the working examples provided at the end of the detailed description, all numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; approximately or reasonably close to the value; nearly). If the imprecision provided by “about” is not otherwise understood in the art with this ordinary meaning, then “about” as used herein indicates at least variations that may arise from ordinary methods of measuring and using such parameters. For example, “about” may comprise a variation of less than or equal to 5%, optionally less than or equal to 4%, optionally less than or equal to 3%, optionally less than or equal to 2%, optionally less than or equal to 1%, optionally less than or equal to 0.5%, and in certain aspects, optionally less than or equal to 0.1%.

In addition, disclosure of ranges includes disclosure of all values and further divided ranges within the entire range, including endpoints and sub-ranges given for the ranges.

Example embodiments will now be described more fully with reference to the accompanying drawings.

As described above, advanced high-strength steels (AHSS) are advantageously used to manufacture vehicle components and assemblies due to their high strength and high ductility. To reduce or prevent corrosion, hot dipping processes may be used to apply a layer of zinc directly onto the AHSS. Prior to applying the zinc layer, the AHSS is annealed in an oxygen-free environment.

Subsequent manufacturing of zinc-coated AHSS may be limited by the susceptibility of AHSS to liquid metal embrittlement (LME). For example, because zinc has a lower melting point than AHSS, the zinc melts first during processes such as resistance spot welding. The liquid zinc may penetrate the AHSS at grain boundaries and result in an assembly having reduced strength and performance due to LME of the AHSS.

In various aspects, the present disclosure provides a high-strength, high-ductility, corrosion-resistant steel having a reduced susceptibility to LME and methods of manufacturing the steel. The steel has higher chromium content and a higher silicon content compared to other AHSS. The steel is pre-oxidized in an oxygen-containing environment to form an oxide layer including a chromium- and silicon-enriched oxide. An anti-corrosion zinc layer is coated on the oxide layer. In certain aspects, the present disclosure also provides methods of manufacturing corrosion-resistant, high-strength steel assemblies formed by resistance spot welding. During resistance spot welding, the oxide layer acts as a barrier to the liquid zinc, thereby reducing or preventing LME of the steel substrate.

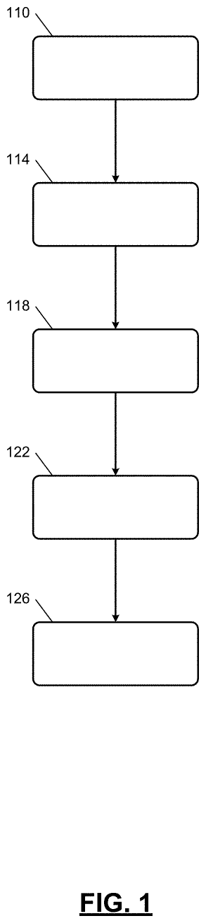

With reference to FIG. 1, a method of manufacturing a high-strength, corrosion-resistant steel assembly according to various aspects of the present disclosure is provided. At 110, the method includes providing a steel substrate. At 114, the method further includes forming an oxide layer on the steel substrate. At 118, the method further includes coating a zinc layer on the oxide layer. At 122, the method further includes forming a component. At 126, the method further includes creating an assembly including the component. In certain aspects, the present disclosure provides a method of manufacturing zinc-coated steel having a reduced susceptibility to LME including steps 110, 114, and 118. Each of these steps is described in a greater detail below.

### Providing Steel Substrate

At 110, the method includes providing a steel substrate. With reference to FIG. 2, a steel substrate 210 according to various aspects of the present disclosure is provided. The steel substrate has an increased chromium and silicon content compared to other AHSS. Examples of the steel are described in International Patent Publication No. WO 2019/127240 (Application No. PCT/CN2017/1 19484; Inventors: Qi Lu, Jiachem Pang, Jianfeng Wang; Filing Date: Dec. 28, 2017; Publication Date: Jul. 4, 2019), incorporated herein by reference in its entirety.

In certain aspects, the steel substrate 210 includes carbon (C), chromium (Cr), silicon (Si), and iron (Fe). The steel substrate may further include manganese (Mn), nickel (Ni), copper (Cu), molybdenum (Mb), vanadium (V), niobium (Nb), boron (B), titanium (Ti), and/or aluminum (Al). The steel substrate 210 includes the chromium in an amount ranging from about 0.5-5 weight percent; the silicon in an amount ranging from about 0.5-2.5 weight percent; the carbon in an amount ranging from 0.01-0.45 weight percent; the manganese in an amount ranging from about 0-4.5 weight percent; the nickel in an amount ranging from about 0-5 weight percent; the copper in an amount ranging from 0-2 weight percent; and a balance iron. In certain aspects, the steel substrate 210 may include the molybdenum in an amount less than 1 weight percent; the vanadium in an amount less than 1 weight percent; the niobium in an amount less than 0.5 weight percent; the boron in an amount less than 0.01 weight percent, the titanium in an amount less than about 0.1 weight percent; and/or the aluminum in an amount less than about 0.5 weight percent.

In one example, the steel substrate 210 consists essentially of chromium in an amount ranging from about 0.5-5 weight percent; silicon in an amount ranging from about 0.5-2.5 weight percent; carbon in an amount ranging from 0.01-0.45 weight percent; manganese in an amount ranging from about 0-4.5 weight percent; nickel in an amount ranging from about 0-5 weight percent; copper in an amount ranging from 0-2 weight percent; molybdenum in an amount less than 1 weight percent; vanadium in an amount less than 1 weight percent; niobium in an amount less than 0.5 weight percent; boron in an amount less than 0.01 weight percent, titanium in an amount less than about 0.1 weight percent; aluminum in an amount less than about 0.5 weight percent; and a balance iron and inevitable impurities. In one example, the steel substrate 210 consists essentially of the chromium in an amount ranging from about 0.5-5 weight percent; the silicon in an amount ranging from about 0.5-2.5 weight percent; the carbon in an amount ranging from 0.01-0.45 weight percent; the manganese in an amount ranging from about 0-4.5 weight percent; the nickel in an amount ranging from about 0-5 weight percent; the copper in an amount ranging from 0-2 weight percent; and a balance iron and inevitable impurities. In one example, the steel substrate 210 consists essentially of the chromium in an amount ranging from about 0.5-5 weight percent; the silicon in an amount ranging from about 0.5-2.5 weight percent; the carbon in an amount ranging from 0.01-0.45 weight percent; and a balance iron and inevitable impurities.

### Forming an Oxide Layer

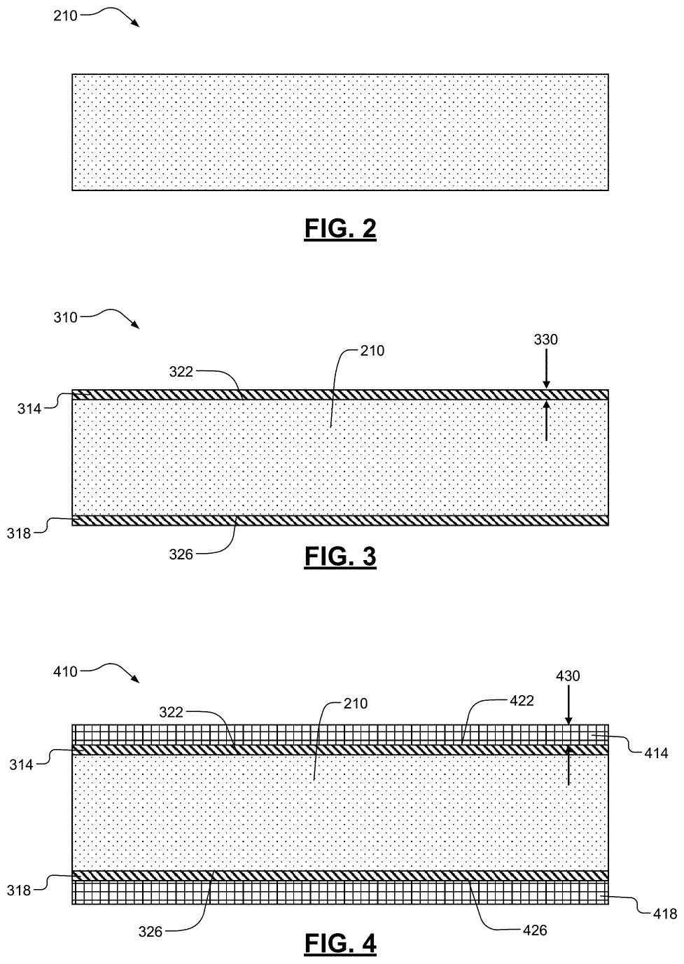

At 114 (FIG. 1), the method includes forming an oxide layer (also referred to as an “oxide-containing layer”). Referring to FIG. 3, a pre-oxidized steel 310 according to various aspects of the present disclosure is provided. The pre-oxidized steel 310 includes the steel substrate 210, a first oxide layer 314, and a second oxide layer 318. The first oxide layer 314 is formed on a first surface 322 of the steel substrate 210. The second oxide layer 318 is formed on a second surface 326 of the steel substrate 210 opposite the first surface 322. In certain other aspects, a pre-oxidized steel substrate according to various aspects of the present disclosure may include only a single oxide layer on a single surface of the steel substrate.

The first and second oxide layers 314, 318 are configured to inhibit liquid metal (e.g., zinc) from penetrating into grain boundaries of the steel substrate 210 and causing LME of the steel substrate 210. Accordingly, the oxide layer is substantially continuous and has a high density and low porosity. As used herein, “substantially continuous,” means that the first and second oxide layers 314, 318 cover substantially the entire first and second surfaces 322, 326, respectively. The oxide layers may have a porosity of less than about 10% (e.g., less than about 9%, less than about 8%, less than about 7%, less than about 6%, less than about 5%, less than about 4%, less than about 3%, less than about 2%, or less than about 1%).

Each of the oxide layers 314, 318 may define a first thickness 330. In certain aspects, the thickness 330 is in a range of about 0.01-5 μm (e.g., 0.01-0.1 μm, 0.1-1 μm, 1-2 μm, 2-3 μm, 3-4 μm, or 4-5 μm). In one example, the first thickness 330 is in a range of about 0.1-1 μm.

The oxide layers 314, 318 include a chromium- and silicon-enriched oxide. In certain aspects, the oxide layers 314, 318 include chromium, silicon, oxygen, and iron. The oxide layers 314, 318 may have a composition of FeₓCr_{y}Si_{z}O. In certain aspects, the oxide layers 314, 318 may include the chromium in an amount ranging from 0.1-50 weight percent, the silicon in an amount ranging from 0.1-30 weight percent, and a balance oxygen and iron.

Formation of the oxide layers 314, 318 is dependent upon a composition of the steel substrate 210 and a controlled annealing process. The controlled annealing process is performed in an environment containing oxygen (O₂). The environment further includes hydrogen (H₂), nitrogen (N₂), or both hydrogen and nitrogen. The oxygen is maintained at a concentration of less than about 10 volume percent (e.g., less than about 9 volume percent, less than about 8 volume percent, less than about 7 volume percent, less than about 6 volume percent, or less than about 5 volume percent). A dew point control is less than about 10° C. (e.g., less than about 9° C., less than about 8° C., less than about 7° C., less than about 6° C., or less than about 5° C.).

The anodizing is performed at a temperature in a range of about 500-950° C. (e.g., about 500-550° C., about 550-600° C., about 600-650° C., about 650-700° C., about 700-750° C., about 750-800° C., about 800-850° C., about 850-900° C., or about 900-950° C.). The anodizing is performed for a duration in a range of about 1-10,000 seconds (e.g., about 1-100 seconds, about 100-250 seconds, about 250-500 seconds, about 500-1,000 seconds, about 1,000-2,500 seconds, about 2,500-5,000 seconds, or about 5,000-10,000 seconds). In one example, the duration is about 60-600 seconds.

### Zinc-Coating the Steel Substrate

At 118 (FIG. 1), the method includes zinc-coating the steel substrate. With reference to FIG. 4, a zinc-coated steel substrate 410 according to various aspects of the present disclosure is provided. The zinc-coated steel substrate 410 includes the steel substrate 210, the first and second oxide layers 314, 318, and first and second zinc layers 414, 418. The first and second zinc layers 414, 418 include zinc. In one example, the first and second zinc layers 414, 418 further include iron, nickel, or both iron and nickel. The first and second zinc layers 414, 418 may consist essentially of zinc, iron, nickel, and inevitable impurities. In another example, the first and second zinc layers 414, 418 consist essentially of zinc and inevitable impurities.

The first zinc layer 414 is disposed on a third surface 422 of the first oxide layer 314. The second zinc layer 418 is disposed on a fourth surface 426 of the second oxide layer 318. In certain aspects, each of the first and second zinc layers 414, 418 define a second thickness 430 in a range of 5-50 μm (e.g., 5-10 μm, 10-20 μm, 20-30 μm, 30-40 μm, or 40-50 μm). In certain other aspects, a zinc-coated steel substrate according to the present disclosure may include only a single zinc layer.

The oxide layers 314, 318 may inhibit adherence of the zinc to the pre-oxidized steel substrate 310 (FIG. 3) in hot dipping processes. Accordingly, in certain aspects of the present disclosure, the zinc layers 414, 418 are applied by a vapor process. Zinc coating may include electric galvanizing (EG), chemical vapor deposition (CVD), physical vapor deposition (PVD), jet vapor deposition (JVD), or any combination thereof, by way of example. In certain aspects, the zinc-coating includes JVD. JVD generally includes vaporizing zinc, spraying zinc droplets onto a moving substrate, and creating a zinc coating as the droplets are solidified in a vacuum environment.

### Stamping the Zinc-Coated Steel Substrate

At 122 (FIG. 1), the method further includes stamping the zinc-coated steel substrate 410 (FIG. 4) to form a component, such as a component for an automotive assembly.

### Creating an Assembly

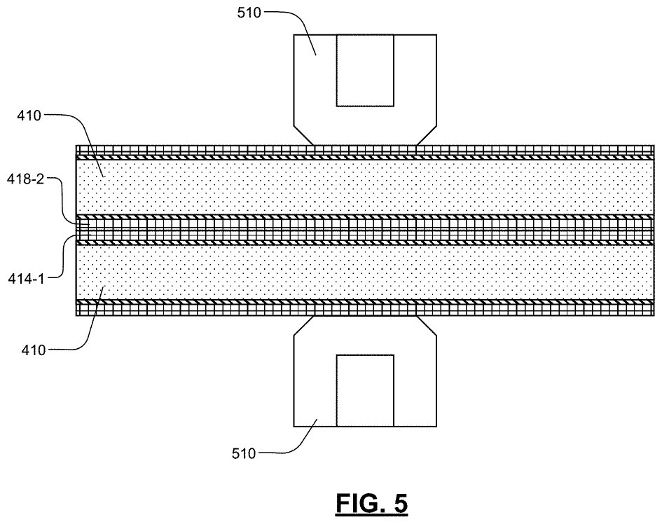

At 126 (FIG. 1), the method further includes creating a high-strength, corrosion-resistant assembly including the component. The assembly may be manufactured via resistance spot welding. Referring to FIG. 5, a schematic of resistance spot welding a pair of the zinc-coated steel substrates 410 (which may be pair of components stamped at step 122) according to various aspects of the present disclosure is provided. The zinc-coated steel substrates 410 are placed between a pair of electrodes 510 and arranged such that respective zinc layers 414-1, 418-2 are in direct communication. A weld nugget (not shown) is created to fix the components to one another. The assembly may include an assembly for an automobile, such as an A-pillar, a B-pillar, a hinge pillar, and/or a door beam. However, the zinc-coated steel and methods of the present disclosure are equally applicable to non-automotive vehicle applications and to non-vehicle applications.

### EXAMPLE 1

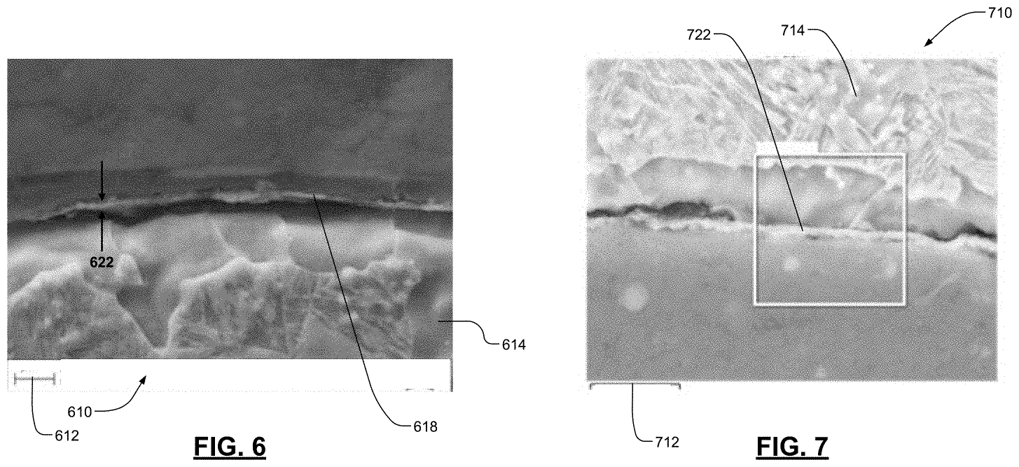

Referring to FIG. 6, a pre-oxidized steel substrate 610 according to various aspects of the present disclosure is provided. A scale 612 is 1 μm. The pre-oxidized steel substrate 610 includes a steel substrate 614 having about 2 weight percent chromium and about 1.5 weight percent silicon. The pre-oxidized steel substrate 610 further includes an oxide layer 618 having a thickness 622 that varies in a range of 0.2-0.6 μm.

### EXAMPLE 2

With reference to FIG. 7, pre-oxidized steel substrate 710 according to various aspects of the present disclosure is provided. A scale 712 is 2.5 μm. The pre-oxidized steel substrate 710 includes a steel substrate 714 and an oxide layer 718. The oxide layer 718 includes chromium, silicon, oxygen, and iron.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method of manufacturing zinc-coated steel having a reduced susceptibility to liquid metal embrittlement (LME), the method comprising:
providing a steel substrate comprising iron, carbon in amount ranging from about 0.01-0.45 weight percent, chromium in an amount ranging from about 0.5-5 weight percent, and silicon in an amount ranging from about 0.5-2.5 weight percent;
forming an oxide-containing layer on a surface of the steel substrate by annealing the steel substrate in an oxygen-containing atmosphere; and
coating a zinc layer on the oxide-containing layer by a spray coating process.

2. The method of claim 1, wherein the forming the oxide-containing layer includes annealing the steel substrate at a dew point control of less than about 10° C.

3. The method of claim 1, wherein the oxygen-containing atmosphere includes the oxygen at less than 10 volume percent and the oxygen-containing atmosphere further includes nitrogen, hydrogen, or both nitrogen and hydrogen.

4. The method of claim 1, wherein the forming the oxide-containing layer includes annealing the steel substrate at a temperature in a range of about 500-950° C.

5. The method of claim 1, wherein the forming the oxide-containing layer includes annealing the steel substrate for a duration of about 1-10,000 seconds.

6. The method of claim 5, wherein the duration is about 60-600 seconds.

7. The method of claim 1, wherein the spray coating process includes electric galvanizing, chemical vapor deposition, physical vapor deposition, jet vapor deposition, or any combination thereof.

8. The method of claim 7, wherein the spray coating process includes jet vapor deposition.

9. The method of claim 1, wherein
the forming the oxide-containing layer includes forming a first oxide-containing layer on a first surface of the steel substrate and forming a second oxide-containing layer on a second surface of the steel substrate opposite the first surface, and
the coating the zinc layer includes coating a first zinc layer on the first oxide-containing layer and coating a second zinc layer on the second oxide-containing layer.

10. The method of claim 1, wherein the oxide-containing layer defines a thickness in a range of about 0.01-5 μm.

11. The method of claim 1, wherein the oxide-containing layer has a porosity of less than or equal to about 10%.

12. A method of creating a zinc-coated-steel assembly having reduced LME, the method comprising:
providing a first zinc-coated steel component including a first steel substrate, a first oxide-containing layer on a surface of the steel substrate, and a first zinc layer on a surface of the oxide-containing layer, the first steel substrate comprising iron, carbon in amount ranging from about 0.01-0.45 weight percent, chromium in an amount ranging from about 0.5-5 weight percent, silicon in an amount ranging from about 0.5-2.5 weight percent;
providing a second zinc-coated steel component including a second steel substrate, a second oxide-containing layer on a surface of the steel substrate, and a second zinc layer on a surface of the oxide-containing layer, the second steel substrate comprising iron, carbon in amount ranging from about 0.01-0.45 weight percent, chromium in an amount ranging from about 0.5-5 weight percent, silicon in an amount ranging from about 0.5-2.5 weight percent;
arranging the first zinc-coated steel component and the second zinc-coated steel component so that the first zinc layer is in contact with the second zinc layer; and
forming the assembly by resistance spot welding the first zinc-coated steel component to the second zinc-coated steel component.

13. The method of claim 12, further comprising:
prior to the forming, stamping the first zinc-coated steel component and stamping the second zinc-coated steel component.

14. A zinc-coated steel component comprising:
a steel substrate comprising iron, carbon in amount ranging from about 0.01-0.45 weight percent, chromium in an amount ranging from about 0.5-5 weight percent, and silicon in an amount ranging from about 0.5-2.5 weight percent;
an oxide-containing layer on a surface of the steel substrate; and
a zinc layer on the oxide-containing layer.

15. The zinc-coated steel component of claim 14, wherein the oxide-containing layer has a porosity of less than or equal to about 10%.

16. The zinc-coated steel component of claim 14, wherein the oxide-containing layer defines a thickness in a range of about 0.01-5 μm.

17. The zinc-coated steel component of claim 16, wherein the thickness is in a range of about 0.1-1 μm.

18. The zinc-coated steel component of claim 14, wherein the oxide-containing layer comprises iron, oxygen, chromium, and silicon.

19. The zinc-coated steel component of claim 18, wherein
the chromium is present in an amount ranging from about 0.1-50 weight percent, and
the silicon is present in an amount ranging from about 0.1-30 weight percent.

20. The zinc-coated steel component of claim 14, wherein
the oxide-containing layer includes a first oxide-containing layer on a first surface of the steel substrate and a second oxide-containing layer on a second surface of the steel substrate opposite the first surface, and
the zinc layer includes a first zinc layer on the first oxide-containing layer and a second zinc layer on the second oxide-containing layer.
